(19) United States
(12) Patent Application Publication
(10) Pub. No.: US 2025/0318181 A1
(43) Pub. Date: Oct. 9, 2025

(54) SEMICONDUCTOR DEVICE AND METHOD FOR MANUFACTURING THE SAME

(71) Applicants: Kabushiki Kaisha Toshiba, Tokyo (JP); Toshiba Electronic Devices & Storage Corporation, Tokyo (JP)

(72) Inventor: Tsuyoshi KACHI, Kanazawa Ishikawa (JP)

(21) Appl. No.: 18/886,997

(22) Filed: Sep. 16, 2024

(30) Foreign Application Priority Data
Apr. 8, 2024 (JP) 2024-062091

(51) Int. Cl. H01L 29/78; H01L 29/06; H01L 29/08; H01L 29/10; H01L 29/66

(52) U.S. Cl. CPC H10D 30/66; H10D 30/0291; H10D 62/109; H10D 62/153; H10D 62/157; H10D 62/393

(57) ABSTRACT

A semiconductor device according to an embodiment includes: a first electrode; a first semiconductor layer of a first conductivity type; a second semiconductor layer of the first conductivity type; a third semiconductor layer of a second conductivity type; a fourth semiconductor layer of the first conductivity type; a fifth semiconductor layer provided around the second semiconductor layer on the first semiconductor layer, the fifth semiconductor layer of the first conductivity type, or the fifth semiconductor layer of the second conductivity type; a second electrode; a third electrode facing the second semiconductor layer and the third semiconductor layer; and a fourth electrode provided in the fifth semiconductor layer adjacent to the second semiconductor layer, the fourth electrode being spaced apart from the first insulating film, and the fourth electrode facing the fifth semiconductor layer.

### CROSS-REFERENCE TO RELATED APPLICATION

This application is based upon and claims the benefit of priority from Japanese Patent Application No. 2024-062091, filed on Apr. 8, 2024, the entire contents of which are incorporated herein by reference.

### FIELD

Embodiments described herein relate generally to a semiconductor device and a method for manufacturing the same.

### BACKGROUND

Semiconductor devices, such as a metal oxide semiconductor field effect transistor (MOSFET), are used for applications such as power conversion. It is desirable for such semiconductor devices to have high reliability.

### BRIEF DESCRIPTION OF THE DRAWINGS

FIGS. 1A and 1B are schematic top views of a main part of a semiconductor device according to a first embodiment;

FIGS. 2A to 2C are schematic cross-sectional views of the semiconductor device according to the first embodiment;

FIGS. 3A and 3B are schematic cross-sectional views of a semiconductor device according to another aspect of the first embodiment;

FIGS. 4A to 4C are schematic cross-sectional views showing a process of manufacturing the semiconductor device according to the first embodiment;

FIGS. 5A to 5C are schematic cross-sectional views showing a process of manufacturing the semiconductor device according to the first embodiment;

FIG. 6 is a schematic top view of a semiconductor device as a comparative form of the first embodiment;

FIGS. 7A to 7C are schematic cross-sectional views of a semiconductor device as a comparative form of the first embodiment;

FIGS. 8A and 8B are schematic cross-sectional views of a semiconductor device according to a second embodiment;

FIGS. 9A to 9C are schematic cross-sectional views showing a process of manufacturing the semiconductor device according to the second embodiment;

FIG. 10 is a schematic cross-sectional view of a semiconductor device according to a third embodiment;

FIG. 11 is a schematic cross-sectional view of a semiconductor device according to another aspect of the third embodiment;

FIGS. 12A to 12C are schematic cross-sectional views showing a process of manufacturing the semiconductor device according to the third embodiment;

FIG. 13 is a schematic cross-sectional view showing a process of manufacturing the semiconductor device according to the third embodiment; and

FIG. 14 is a schematic cross-sectional view of a semiconductor device according to a fourth embodiment.

### DETAILED DESCRIPTION

Hereinafter, embodiments will be described with reference to the diagrams. In the following description, the same members and the like are denoted by the same reference numerals, and the description of the members and the like once described will be omitted as appropriate.

In this specification, in order to show the positional relationship of components and the like, the upper direction of the diagram is described as “upper” and the lower direction of the diagram is described as “lower”. In this specification, the concepts of “upper” and “lower” do not necessarily indicate the relationship with the direction of gravity.

Hereinafter, a case where the first conductivity type is n-type and the second conductivity type is p-type will be described as an example.

In the following description, when there are notations of n⁺, n, n⁻, p⁺, p, and p⁻, these indicate the relative high and low of the impurity concentration in each conductivity type. That is, n⁺ indicates that the n-type impurity concentration is relatively higher than n, and n indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

### First Embodiment

A semiconductor device of embodiments includes: a first electrode; a first semiconductor layer of a first conductivity type provided on the first electrode; a second semiconductor layer of the first conductivity type provided on the first semiconductor layer, and the second semiconductor layer having a lower concentration of impurities of the first conductivity type than the first semiconductor layer; a third semiconductor layer of a second conductivity type provided on the second semiconductor layer; a fourth semiconductor layer of the first conductivity type provided on the third semiconductor layer; a fifth semiconductor layer provided around the second semiconductor layer on the first semiconductor layer, the fifth semiconductor layer of the first conductivity type and having a lower concentration of impurities of the first conductivity type than the second semiconductor layer, or the fifth semiconductor layer of the second conductivity type; a second electrode provided in the third semiconductor layer; a third electrode provided in the second semiconductor layer and the third semiconductor layer, the third electrode facing the second semiconductor layer and the third semiconductor layer via a first insulating film; and a fourth electrode provided in the fifth semiconductor layer adjacent to the second semiconductor layer, the fourth electrode being spaced apart from the first insulating film, and the fourth electrode facing the fifth semiconductor layer via a second insulating film.

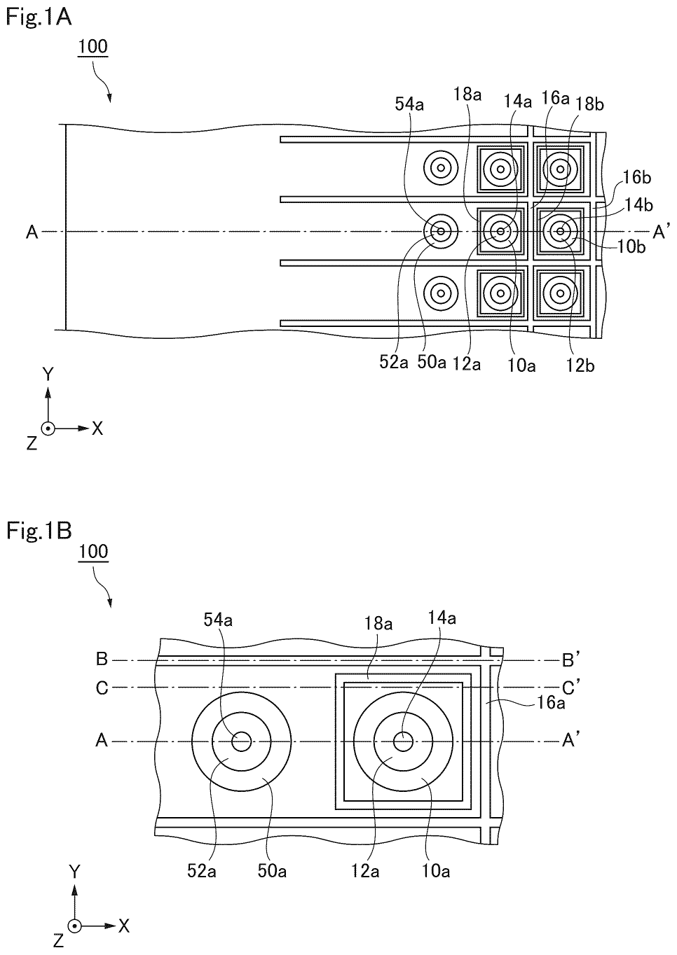

FIGS. 1A and 1B are schematic top views of a semiconductor device 100 of embodiments.

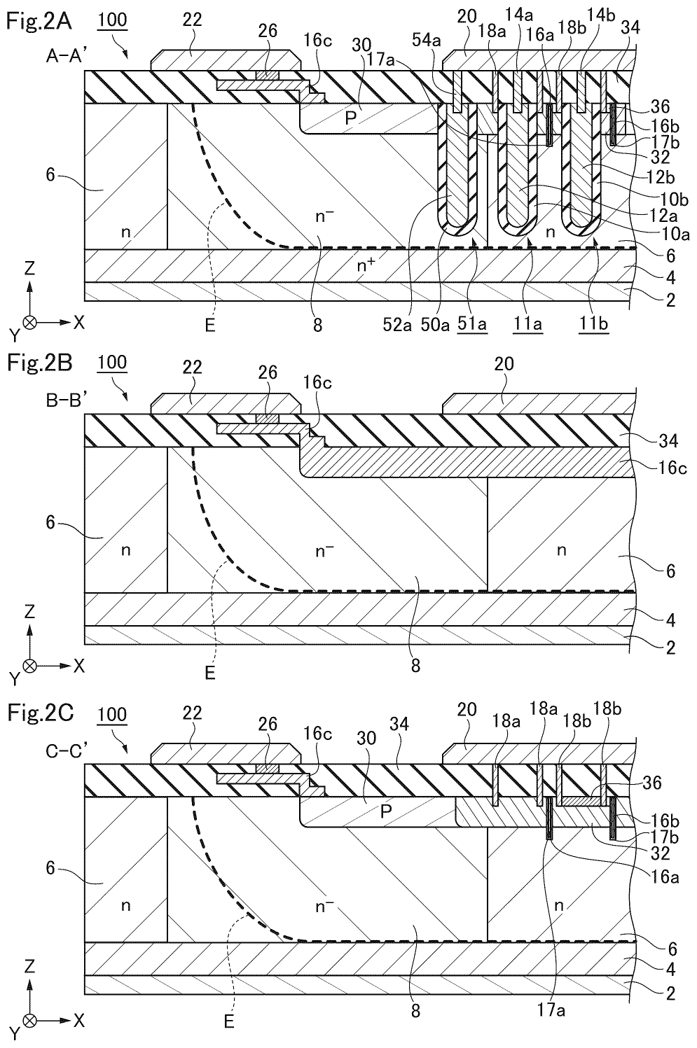

FIGS. 2A to 2C are schematic cross-sectional views of the semiconductor device 100 of embodiments. FIG. 2A is a schematic diagram of an A-A′ cross section shown in FIG. 1. FIG. 2B is a schematic diagram of a B-B′ cross section shown in FIG. 1. FIG. 2C is a schematic diagram of a C-C′ cross section shown in FIG. 1.

In FIGS. 1A and 1B, a source wiring 20, a gate wiring 22, a first insulating layer 34, a third wiring 26, an extension portion 16c of a gate electrode (a part of the gate electrode), and the like are omitted.

The semiconductor device 100 of embodiments will be described with reference to FIGS. 1A to 2C.

The semiconductor device 100 is, for example, a vertical MOSFET.

A drain electrode 2 (an example of the first electrode) is an electrode that functions as a drain electrode of the MOSFET. The drain electrode 2 contains a conductive material such as aluminum (Al).

A drain layer 4 (an example of the first semiconductor layer) is provided on the drain electrode 2. The drain layer 4 is electrically connected to the drain electrode 2. The drain layer 4 is a layer that functions as a drain of the MOSFET. The drain layer 4 contains, for example, an n⁺-type semiconductor material.

A drift layer 6 (an example of the second semiconductor layer) is provided on the drain layer 4. The drift layer 6 is a layer that functions as a drift layer of the MOSFET. The drift layer 6 contains, for example, an n-type semiconductor material. The n-type impurity concentration of the drift layer 6 is lower than the n-type impurity concentration of the drain layer 4.

Here, an X direction, a Y direction perpendicular to the X direction, and a Z direction perpendicular to the X and Y directions are defined. The drain electrode 2, the drain layer 4, and the drift layer 6 are layers provided in parallel to the XY plane. The Z direction is a direction from the drain electrode 2 toward the drift layer 6.

A base layer 32 (an example of the third semiconductor layer) is provided on the drift layer 6. In addition, a part of the base layer 32 is provided, for example, on a termination layer 8, which will be described later. The base layer 32 is a layer that functions as a base of the MOSFET. The base layer 32 is a layer that forms a channel when a charge is applied to a gate electrode 16, which will be described later, so that carriers can flow between a source layer 36, which will be described later, and the drain layer 4. The base layer 32 contains, for example, a p-type semiconductor material.

The source layer 36 (an example of the fourth semiconductor layer) is provided on the base layer 32. The source layer 36 is a region that functions as a source of the MOSFET. When an appropriate voltage is applied to the gate electrode 16, carriers flow between the source layer 36 and the drain layer 4. The source layer 36 contains, for example, an n⁺-type semiconductor material.

The termination layer 8 (an example of the fifth semiconductor layer) is provided around the drift layer 6 on the drain layer 4. The termination layer 8 contains, for example, an n⁻-type semiconductor material. The n-type impurity concentration of the termination layer 8 is lower than the n-type impurity concentration of the drift layer 6.

A RESURF layer 30 (an example of the sixth semiconductor layer) is provided on the termination layer 8 and is connected to the base layer 32. For example, the RESURF layer 30 is connected to the base layer 32 provided on the termination layer 8. The RESURF layer 30 contains, for example, a p-type semiconductor material. The p-type impurity concentration of the RESURF layer 30 is lower than the p-type impurity concentration of the base layer 32.

A first trench 11a and a first trench 11b are provided so as to reach the drift layer 6 from above the base layer 32. In addition, the first trench 11b is provided so as to reach the drift layer 6 from above the source layer 36. On the other hand, the source layer 36 is not provided in a region where the first trench 11a is provided.

A first field plate electrode 12b (an example of the third electrode) is provided in the first trench 11b so as to face the drift layer 6, the base layer 32, and the source layer 36 via a first insulating film 10b. A first field plate electrode 12a (an example of the third electrode) is provided in the first trench 11a so as to face the drift layer 6 and the base layer 32 via a first insulating film 10a. A first field plate electrode 12 is provided to increase the breakdown voltage of the MOSFET by reducing the concentration of a reverse electric field between the gate electrode 16 and the drain electrode 2, for example. The first field plate electrode 12 contains a conductive material such as polysilicon containing impurities.

A second trench 51a is provided in the termination layer 8 adjacent to the drift layer 6 so as to be spaced apart from the first trench 11. For example, the second trench 51a is provided so as to reach the termination layer 8 from above the base layer 32 and the RESURF layer 30 provided on the termination layer 8.

A second field plate electrode 52a (an example of the fourth electrode) is provided in the second trench 51a so as to face the termination layer 8, the RESURF layer 30, and the base layer 32 via a second insulating film 50a. The second insulating film 50a is provided so as to be spaced apart from the first insulating film 10a. The second field plate electrode 52a is provided to increase the breakdown voltage of the MOSFET by reducing the concentration of a reverse electric field between the gate electrode 16 and the drain electrode 2, for example. A second field plate electrode 52 contains a conductive material such as polysilicon containing impurities.

In the semiconductor device 100 of embodiments, as shown in FIG. 1A, the field plate electrodes (the first field plate electrode 12 and the second field plate electrode 52) are arranged so as to be separated from each other in the X and Y directions.

The first insulating layer 34 is provided on the drift layer 6, the termination layer 8, the base layer 32 and the source layer 36. The first insulating layer 34 contains an insulating material such as silicon oxide.

The source wiring 20 (an example of the first wiring) is provided, for example, on the first insulating layer 34 on the base layer 32. The source wiring 20 contains a conductive material such as Al.

The gate wiring 22 (an example of the second wiring) is provided, for example, on the first insulating layer 34 on the termination layer 8. The gate wiring 22 contains a conductive material such as Al.

A connection wiring 18a is provided, for example, around the first trench 11a when viewed from above. The connection wiring 18a electrically connects the base layer 32 and the source wiring 20 to each other.

A connection wiring 18b is provided, for example, around the first trench 11b when viewed from above. The connection wiring 18b electrically connects the base layer 32 and the source wiring 20 to each other.

A connection wiring 14a electrically connects the first field plate electrode 12a and the source wiring 20 to each other. The connection wiring 14b electrically connects the first field plate electrode 12b and the source wiring 20 to each other. A connection wiring 54 electrically connects the second field plate electrode 52 and the source wiring 20 to each other.

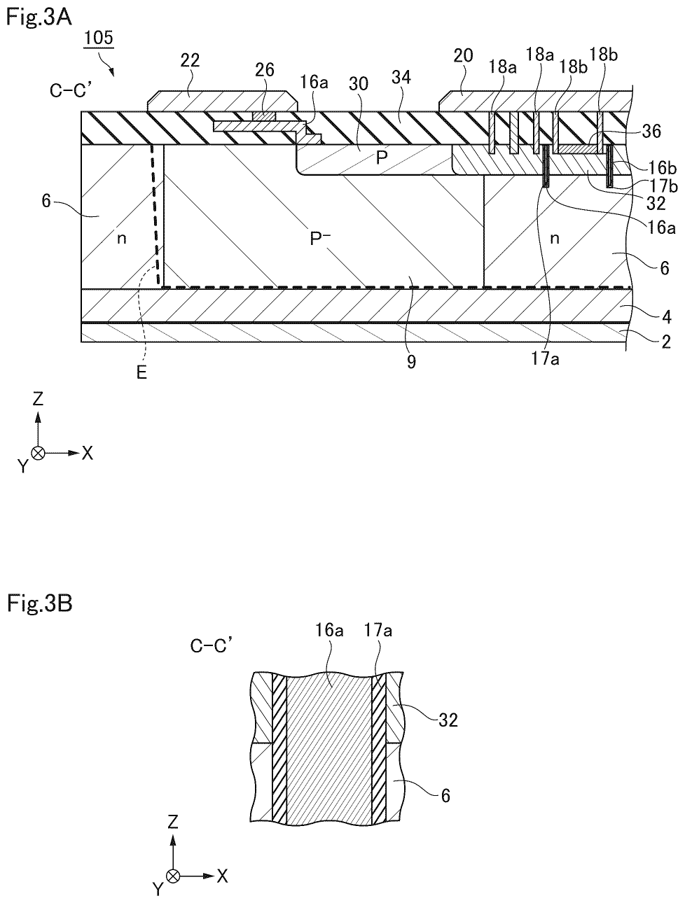

A gate electrode 16a is provided in the base layer 32 between the first insulating film 10a and the first insulating film 10b. A gate electrode 16b is provided in the base layer 32. The gate electrode 16a and the gate electrode 16b are electrically connected to the gate wiring 22, for example, through the extension portion 16c of the gate electrode (a part of the gate electrode) (FIG. 2B) provided in the base layer 32 and the third wiring 26 provided in the first insulating layer 34 on the termination layer 8. The gate electrode 16 contains a conductive material such as polysilicon containing impurities. The gate electrode 16 is an example of the second electrode. In addition, as shown in FIG. 3B, a gate insulating film 17 is provided between the gate electrode 16 and the drift layer 6, the base layer 32, and the source layer 36.

FIGS. 3A and 3B are schematic cross-sectional view of a semiconductor device 105 according to another aspect of embodiments. FIG. 3A is a schematic cross-sectional view of the C-C′ cross section of the schematic top view shown in FIG. 1. Instead of the n⁻-type termination layer 8, a p--type termination layer 9 is provided. FIG. 3B is a schematic enlarged view of the vicinity of the gate electrode 16 and the gate insulating film 17.

In addition, FIGS. 2A to 3B also show a depletion layer end E when a reverse electric field is applied.

When Si is used as a semiconductor material, for example, arsenic (As), phosphorus (P), or antimony (Sb) can be used as an n-type impurity, and B (boron) can be used as a p-type impurity.

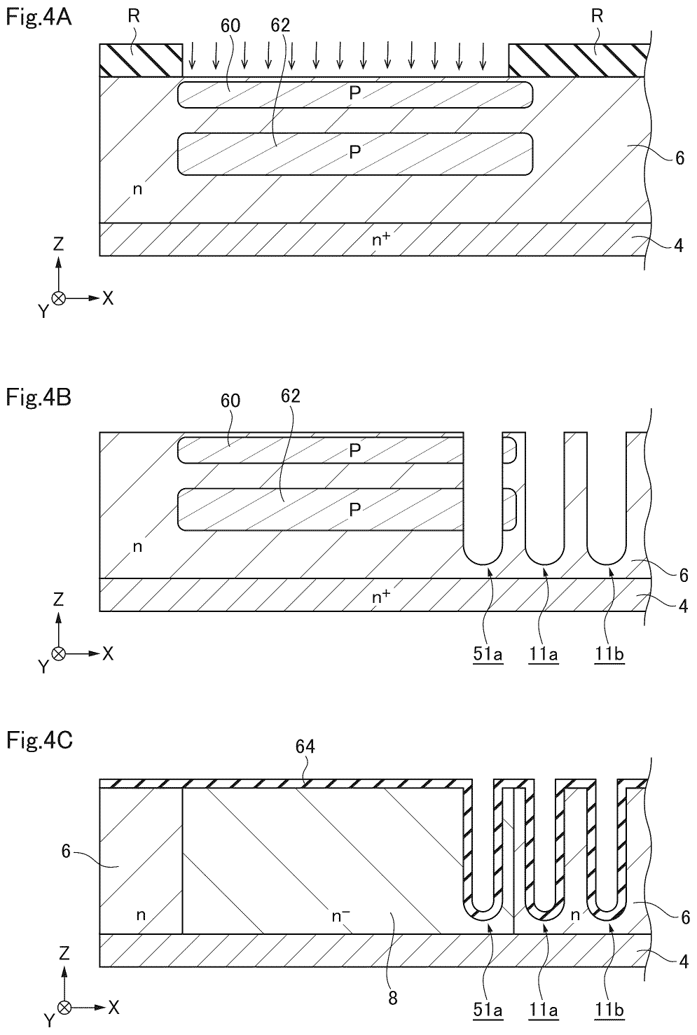

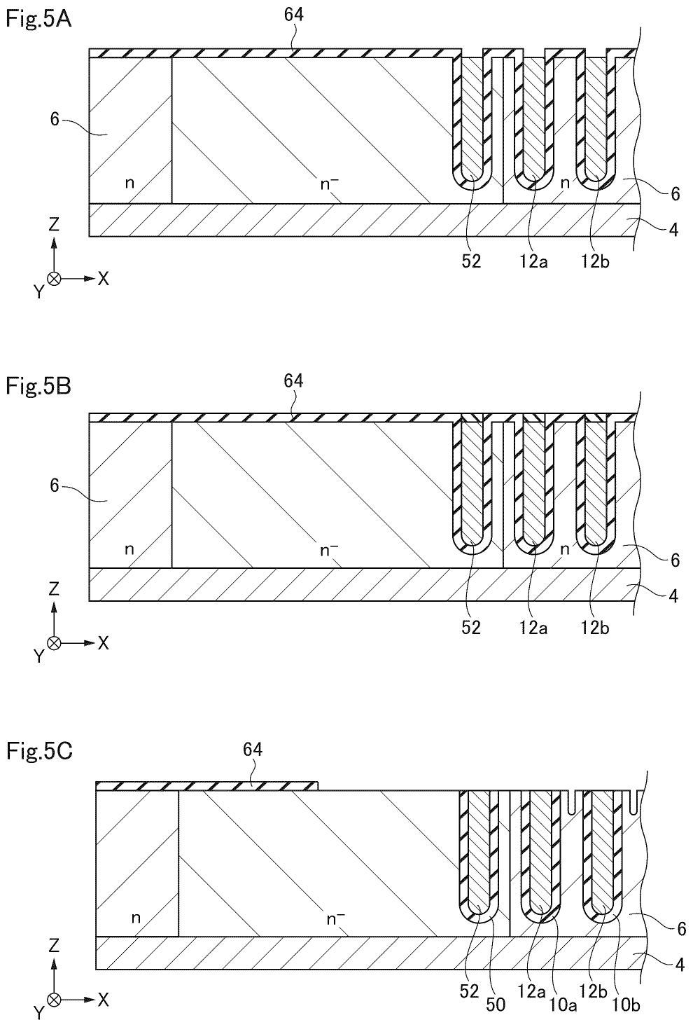

FIGS. 4A to 5C are schematic cross-sectional views showing a process of manufacturing the semiconductor device of embodiments.

A method for manufacturing a semiconductor device of embodiments includes: forming a tenth semiconductor layer of second conductivity type in a layer of a second semiconductor layer of first conductivity type, the layer of the second semiconductor layer becoming a fifth semiconductor layer; forming a first trench in the second semiconductor layer, the tenth semiconductor layer being not formed in the second semiconductor layer; forming a second trench in the second semiconductor layer in which the tenth semiconductor layer is formed; forming a fourth insulating film on the second semiconductor layer and inside the first trench and the second trench; and forming a fifth semiconductor layer of first conductivity type or second conductivity type having a lower concentration of impurities of first conductivity type than the second semiconductor layer by diffusing impurities of second conductivity type contained in the tenth semiconductor layer into the second semiconductor layer, the tenth semiconductor layer being formed in the second semiconductor layer.

First, using a resist mask R provided on a portion where the termination layer 8 is not formed, a p-type semiconductor layer 62 (an example of the tenth semiconductor layer) and a p-type semiconductor layer 60 (an example of the tenth semiconductor layer) provided on the semiconductor layer 62 are formed from above a layer as that becomes the termination layer 8 of the drift layer 6 on the drain layer 4.

Then, the resist mask R is removed by, for example, ashing. Then, the first trench 11 is formed in the drift layer 6 where the semiconductor layer 62 and the semiconductor layer 60 are not formed. In addition, a second trench 51 is formed in the drift layer 6 in which the semiconductor layer 62 and the semiconductor layer 60 are formed and which is adjacent to the first trench 11 (FIG. 4B).

Then, an insulating film 64 containing silicon oxide is formed on the drift layer 6 and inside the first trench 11 and the second trench 51 by using a thermal oxidation method, for example. Here, when the insulating film 64 is formed, for example, the n⁻-type termination layer 8 is formed by thermal diffusion of p-type impurities in the semiconductor layers 60 and 62.

Although the p-type semiconductor layer 60 and the p-type semiconductor layer 62 are formed herein, the number and form of p-type semiconductor layers to be formed are not particularly limited to those shown in FIGS. 4A and 4B. In addition, it is also possible to form the p⁻-type termination layer 9 around the drift layer 6 by increasing the amount of p-type impurities injected.

Then, the first field plate electrode 12 is formed in the first trench 11 by using, for example, a chemical vapor deposition (CVD) method. In addition, the second field plate electrode 52 is formed in the second trench 51 (FIG. 5A).

Then, an insulating film 66 is formed on the first field plate electrode 12 and the second field plate electrode 52 by using, for example, a thermal oxidation method or a CVD method. Then, a gate trench 68 is formed between the first field plate electrode 12 and the first field plate electrode 12. The depth of the gate trench 68 is shallower than the depth of the first trench 11 and the depth of the second trench 51.

Then, parts of the insulating film 66 and the insulating film 64 are removed by using, for example, an etching method (FIG. 5C).

Then, the gate electrode 16 is formed in the gate trench 68. In addition, the extension portion 16c of the gate electrode is formed on the insulating film 64. Then, the RESURF layer 30 is formed on the drift layer 6 and on the termination layer 8 adjacent to the drift layer 6 by using, for example, an ion implantation method. In addition, the base layer 32 is formed on the drift layer 6 by using, for example, an ion implantation method. Then, the source layer 36 is formed on the base layer 32 by using, for example, an ion implantation method.

Then, the third wiring 26, the connection wiring 18a, the connection wiring 18b, the connection wiring 14a, the connection wiring 14b, the connection wiring 54, the first insulating layer 34, the source wiring 20, and the gate wiring 22 are formed as appropriate, thereby obtaining the semiconductor device 100 of embodiments.

Next, the function and effect of the semiconductor device of embodiments will be described.

In a MOSFET having a field plate electrode, by depleting the drift layer with the electric field from the field plate electrode, it is possible to achieve both a high breakdown voltage and a low on-resistance even in the drift layer with a high n-type impurity concentration compared with a one-dimensional junction such as a pn junction.

However, when the n-type impurity concentration in the drift layer is high, the termination layer where no field plate electrode is arranged is particularly less depleted than the FET cell portion where the field plate electrode is arranged. For this reason, there have been problems such as a decrease in breakdown voltage in reliability evaluation tests such as a high temperature reverse bias test (HTRB test).

In addition, in a MOSFET having a field plate electrode, it is required to arrange the gate electrode only further inward than a region where the field plate electrode connected to the source wiring is arranged. This is because, if the gate electrode is arranged in a region that is not depleted because a field plate electrode is not arranged, a drain voltage is applied to the gate insulating film, which may cause dielectric breakdown of the gate insulating film.

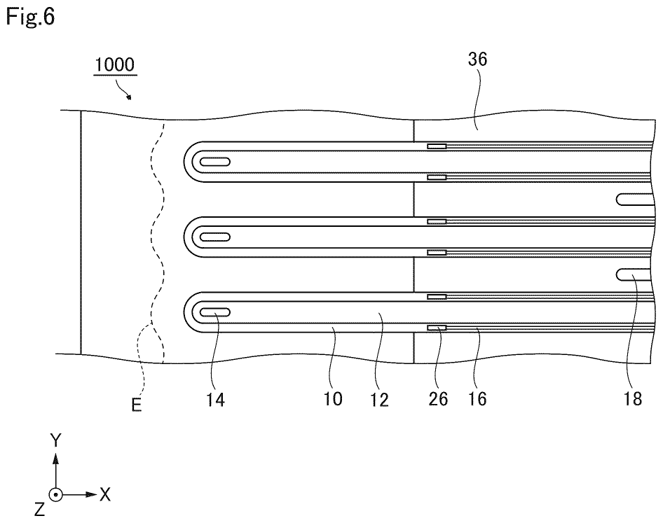

FIG. 6 is a schematic top view of a semiconductor device 1000 as a comparative form. FIG. 6 is a schematic top view showing a connection state between the first field plate electrode 12 and the source wiring 20 and a connection state between the gate electrode 16 and the gate wiring 22 in the semiconductor device 1000 in which the first field plate electrode 12 is provided so as to extend in the X direction.

The gate electrode 16 can be connected to a gate wiring (not shown), which is provided on the source layer 36, through the third wiring 26. In addition, the first field plate electrode 12 can be connected to a source wiring (not shown), which is provided on the connection wiring 14, through the connection wiring 14. Thus, in the case of a semiconductor device in which the field plate electrode is provided so as to extend in the X direction, there is a large degree of freedom in the connection between the gate electrode and the gate wiring and the connection between the field plate electrode and the source wiring in the X direction. Therefore, it is possible to arrange the gate electrode in the depleted region.

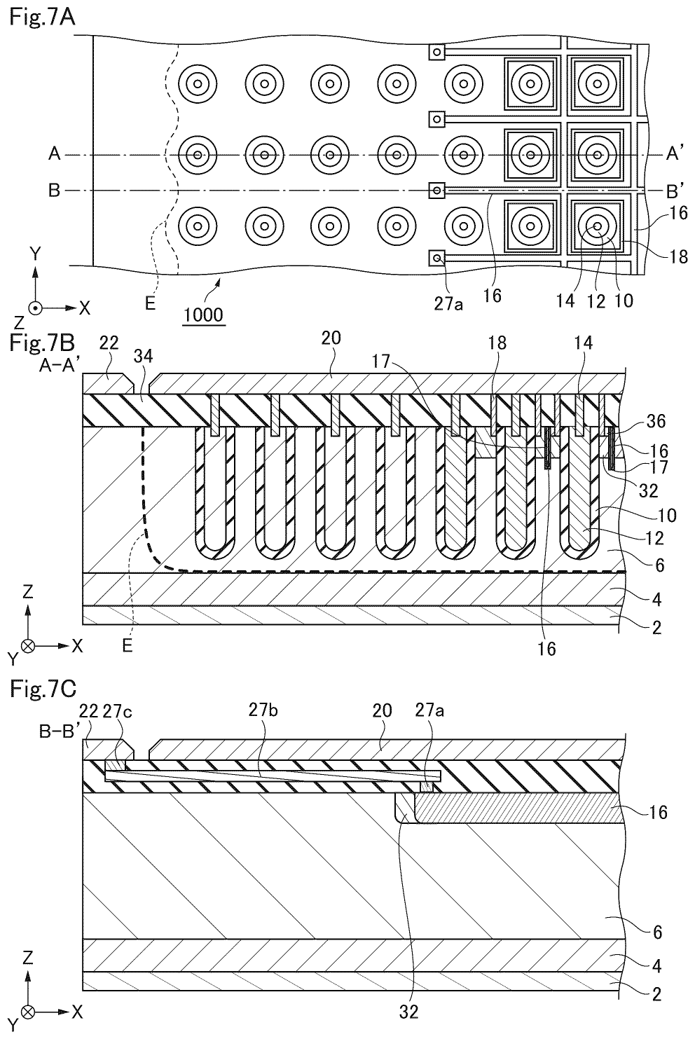

FIGS. 7A to 7C are schematic diagrams of a semiconductor device 1100 as a comparative form. As in the semiconductor device 1100, by arranging field plate electrodes so as to be separated from each other in the X and Y directions, it is possible to obtain a low on-resistance and a small output capacitance Coss. On the other hand, since the gate electrode 16 cannot be arranged in a region that is not depleted, the connection between the gate electrode 16 and the gate wiring 22 is made, for example, by providing a wiring 27 (wiring 27a, wiring 27b, and wiring 27c) between the drift layer 6 and the source wiring 20. As a result, a two-layer wiring structure in which the wiring 27b and the source wiring 20 are stacked is formed. For this reason, the manufacturing process becomes complicated.

Therefore, the semiconductor device of embodiments includes: a first electrode; a first semiconductor layer of a first conductivity type provided on the first electrode; a second semiconductor layer of the first conductivity type provided on the first semiconductor layer, and the second semiconductor layer having a lower concentration of impurities of the first conductivity type than the first semiconductor layer; a third semiconductor layer of a second conductivity type provided on the second semiconductor layer; a fourth semiconductor layer of the first conductivity type provided on the third semiconductor layer; a fifth semiconductor layer provided around the second semiconductor layer on the first semiconductor layer, the fifth semiconductor layer of the first conductivity type and having a lower concentration of impurities of the first conductivity type than the second semiconductor layer, or the fifth semiconductor layer of the second conductivity type; a second electrode provided in the third semiconductor layer; a third electrode provided in the second semiconductor layer and the third semiconductor layer, the third electrode facing the second semiconductor layer and the third semiconductor layer via a first insulating film; and a fourth electrode provided in the fifth semiconductor layer adjacent to the second semiconductor layer, the fourth electrode being spaced apart from the first insulating film, and the fourth electrode facing the fifth semiconductor layer via a second insulating film.

In the semiconductor device 100, the n⁻-type termination layer 8 or the p⁻-type termination layer 9 is provided. For this reason, even if a field plate electrode is not provided in the n⁻-type termination layer 8 or the p⁻-type termination layer 9, the depletion layer can easily spread outside the termination layer 8 or 9. This makes it possible to avoid the above-mentioned problem that “if the gate electrode is arranged in a region that is not depleted, a drain voltage is applied to the gate insulating film to cause dielectric breakdown of the gate insulating film”. Therefore, it is possible to provide a highly reliable semiconductor device.

In addition, by providing the RESURF layer 30, the depletion layer can more easily spread outside the termination layer 8 or 9.

In addition, by using the third wiring 26 that is provided in the first insulating layer 34 on the termination layer 8 to electrically connect the gate electrode 16 and the gate wiring 22 to each other, the film thickness of the first insulating layer 34 between a portion where the gate electrode 16 extends to the termination layer 8 and the termination layer 8 can be reduced. Therefore, since it is possible to reduce the step on the surface when the first insulating layer 34 is formed, processing of the wiring formed in the first insulating layer 34 becomes easier.

According to the semiconductor device of embodiments, it is possible to provide a highly reliable semiconductor device.

### Second Embodiment

A semiconductor device of embodiments is different from the semiconductor device according to the first embodiment in that a fifth electrode provided in the fifth semiconductor layer, the fifth electrode facing the fifth semiconductor layer via a third insulating film, the third insulating film being spaced apart from the second insulating film, and the fourth electrode being provided between the third electrode and the fifth electrode. Here, the description of the content overlapping the first embodiment will be omitted.

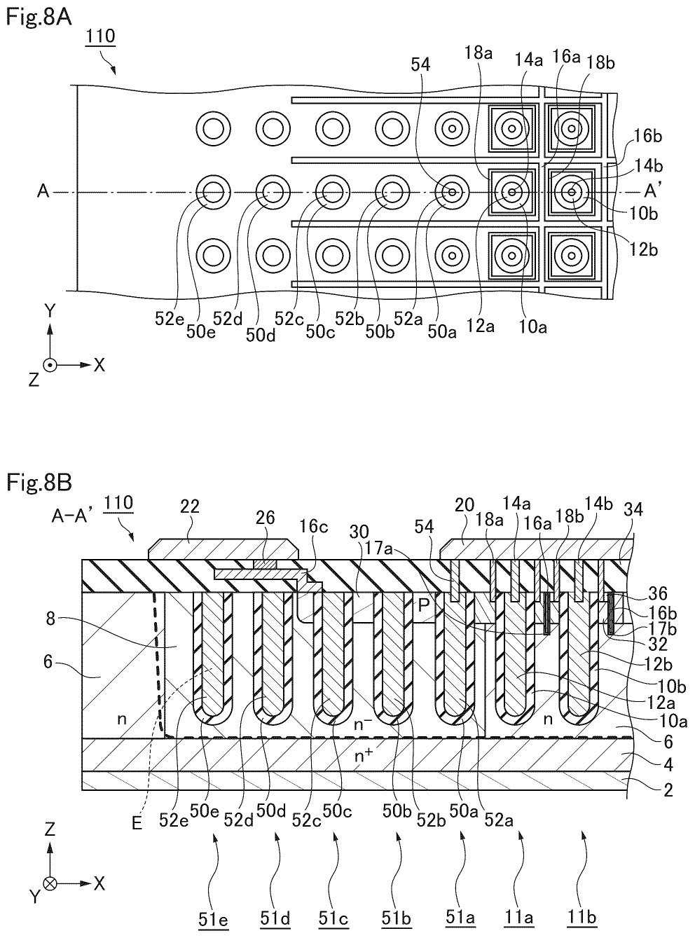

FIGS. 8A and 8B are schematic diagrams of a semiconductor device 110 of embodiments.

In the semiconductor device 105, in addition to the second trench 51a, for example, a second trench 51b, a second trench 51c, a second trench 51d, and a second trench 51e are provided in the termination layer 8. In addition, the number of second trenches provided in the termination layer 8 is not limited to that shown in FIGS. 8A and 8B.

The second field plate electrode 52b is provided in the termination layer 8 so as to face the termination layer 8 via a second insulating film 50b spaced apart from the second insulating film 50a. The second field plate electrode 52c is provided in the termination layer 8 so as to face the termination layer 8 via a second insulating film 50c spaced apart from the second insulating film 50b. The second field plate electrode 52d is provided in the termination layer 8 so as to face the termination layer 8 via a second insulating film 50d spaced apart from the second insulating film 50c. The second field plate electrode 52e is provided in the termination layer 8 so as to face the termination layer 8 via a second insulating film 50e spaced apart from the second insulating film 50d.

In addition, the second field plate electrode 52b, the second field plate electrode 52c, the second field plate electrode 52d, and the second field plate electrode 52e are not electrically connected to the source wiring 20.

In the semiconductor device 110 of embodiments, the second insulating film 50a is an example of the second insulating film. In addition, the second insulating film 50b is an example of the third insulating film. In addition, the second field plate electrode 52b is an example of the fifth electrode.

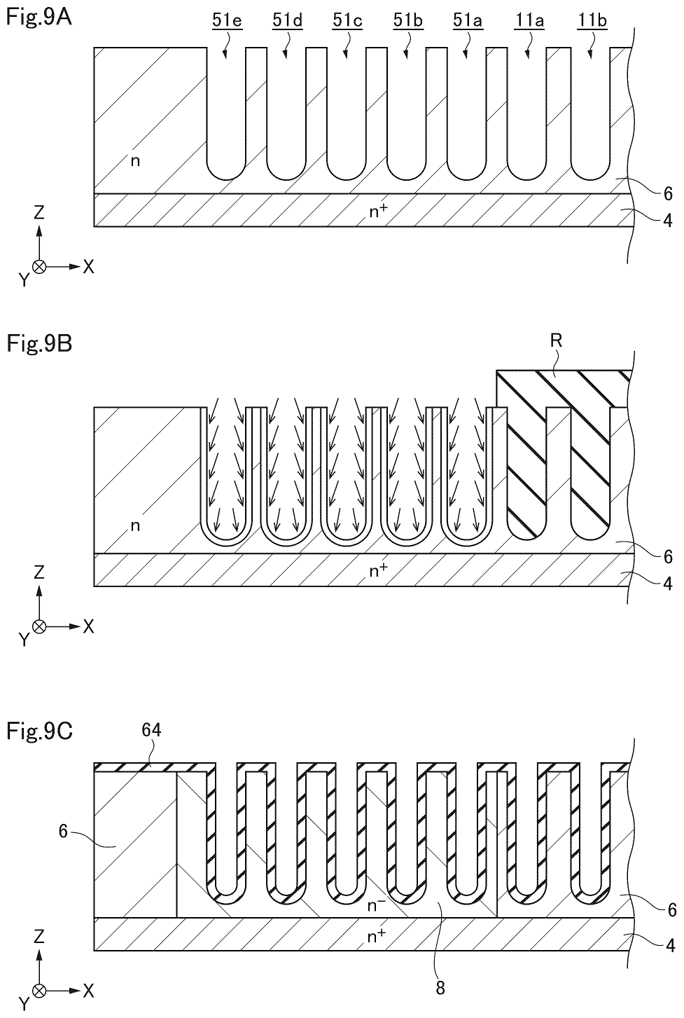

FIGS. 9A to 9C are schematic diagrams showing a process of manufacturing the semiconductor device 110 of embodiments.

As shown in FIG. 9A, the second trench 51b, the second trench 51c, the second trench 51d, and the second trench 51e are also formed in a layer of the drift layer 6 in which the termination layer 8 is to be formed.

Then, the resist mask R is formed inside the first trenches 11a and 11b. Then, ion implantation of p-type impurities is performed from above the layer in which the termination layer 8 is to be formed (FIG. 9B).

Then, the resist mask R is removed by, for example, ashing. Then, the insulating film 64 containing silicon oxide is formed on the drift layer 6 and inside the first trench 11 and the second trench 51 by using a thermal oxidation method, for example. Here, when the insulating film 64 is formed, the p-type impurities in the semiconductor layers 60 and 62 are thermally diffused to form the n⁻-type termination layer 8 around the drift layer 6 (FIG. 9C). The subsequent steps are the same as those shown in FIG. 5 and subsequent steps in the process of manufacturing the semiconductor device 100 according to the first embodiment.

In the case of the semiconductor device 110 of embodiments, the termination layer 8 is formed by performing ion implantation of p-type impurities using the second trench 51b, the second trench 51c, the second trench 51d, and the second trench 51e provided in a portion where the termination layer 8 is to be formed. Due to the presence of the second trench 51b, the second trench 51c, the second trench 51d, and the second trench 51e, ion implantation can be easily performed throughout the drift layer 6 to form the termination layer 8 even if ion implantation using high energy is not performed. This is particularly beneficial when using the thick drift layer 6 to manufacture a MOSFET with a high breakdown voltage.

Through the semiconductor device 110 of embodiments, it is also possible to provide a highly reliable semiconductor device.

### Third Embodiment

A semiconductor device of embodiments includes: a first electrode; a first semiconductor layer of a first conductivity type provided on the first electrode; a second semiconductor layer of the first conductivity type provided on the first semiconductor layer, and the second semiconductor layer having a lower concentration of impurities of the first conductivity type than the first semiconductor layer; a third semiconductor layer of a second conductivity type provided on the second semiconductor layer; a fourth semiconductor layer of the first conductivity type provided on the third semiconductor layer; a seventh semiconductor layer of the second conductivity type provided on the second semiconductor layer around the third semiconductor layer, the seventh semiconductor layer being connected to the third semiconductor layer, and the seventh semiconductor layer having a lower concentration of impurities of the second conductivity type than the third semiconductor layer; an eighth semiconductor layer of the second conductivity type provided in the second semiconductor layer below the seventh semiconductor layer, and the eighth semiconductor layer having a lower concentration of impurities of the second conductivity type than the third semiconductor layer; a second electrode provided in the third semiconductor layer; a third electrode provided in the second semiconductor layer and the third semiconductor layer, the third electrode facing the second semiconductor layer and the third semiconductor layer via a first insulating film; and a fourth electrode provided in the seventh semiconductor layer, in the eighth semiconductor layer, and in the second semiconductor layer between the seventh semiconductor layer and the eighth semiconductor layer, the fourth electrode facing the seventh semiconductor layer, the eighth semiconductor layer, and the second semiconductor layer via a second insulating film. Here, the description of the content overlapping the first and second embodiments will be omitted.

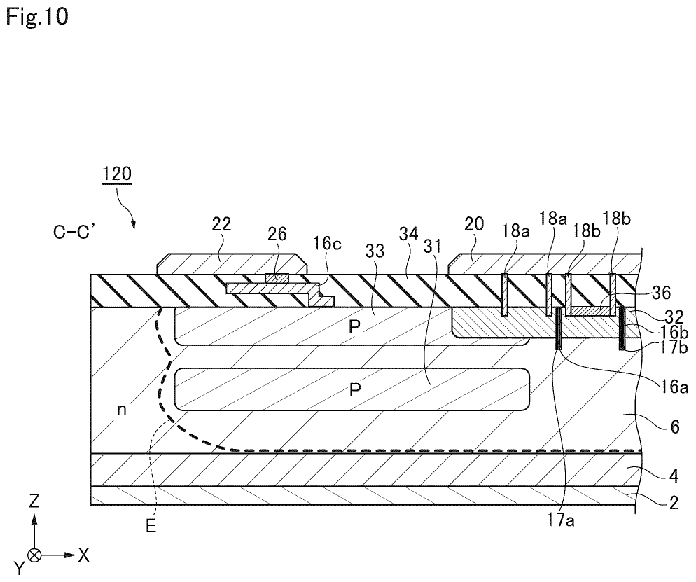

FIG. 10 is a schematic cross-sectional view of a semiconductor device 120 of embodiments. FIG. 10 is a schematic cross-sectional view corresponding to the cross-sectional view taken along the line C-C′ in FIG. 1A.

In the semiconductor device 120, the termination layer 8 or the termination layer 9 is not provided.

A p-type seventh semiconductor layer 33 is provided on the drift layer 6 around the base layer 32. The seventh semiconductor layer 33 is connected to the base layer 32. The p-type impurity concentration of the seventh semiconductor layer 33 is lower than the p-type impurity concentration of the base layer 32.

A p-type eighth semiconductor layer 31 is provided in the drift layer 6 below the seventh semiconductor layer 33. The p-type impurity concentration of the eighth semiconductor layer 31 is lower than the p-type impurity concentration of the base layer 32.

In the semiconductor device 120, the second trench 51a is provided so as to be spaced apart from the first trench 11a and reach the drift layer 6 below the eighth semiconductor layer 31 from above the base layer 32 and the seventh semiconductor layer 33, for example.

The second field plate electrode 52a (an example of the fourth electrode) is provided in the second trench 51a so as to face the drift layer 6, the seventh semiconductor layer 33, the eighth semiconductor layer 31, and the base layer 32 via the second insulating film 50a. The second insulating film 50a is provided so as to be spaced apart from the first insulating film 10a.

The third wiring 26 is provided in the first insulating layer 34 on the seventh semiconductor layer 33.

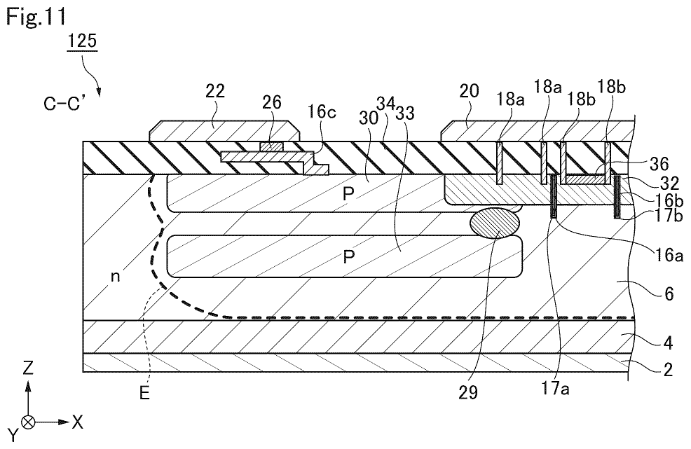

FIG. 11 is a schematic cross-sectional view of a semiconductor device 125 according to another aspect of embodiments.

A p-type ninth semiconductor layer 29 is provided between the seventh semiconductor layer 33 and the eighth semiconductor layer 31 and is connected to the seventh semiconductor layer 33 and the eighth semiconductor layer 31. The p-type impurity concentration of the ninth semiconductor layer 29 is lower than the p-type impurity concentration of the base layer 32.

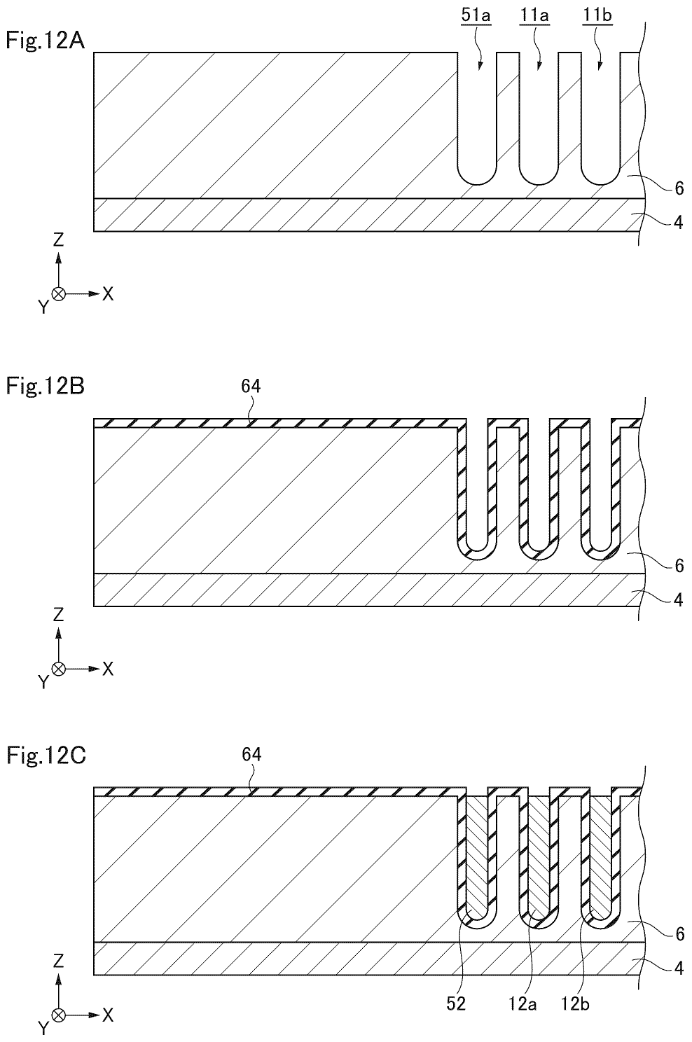

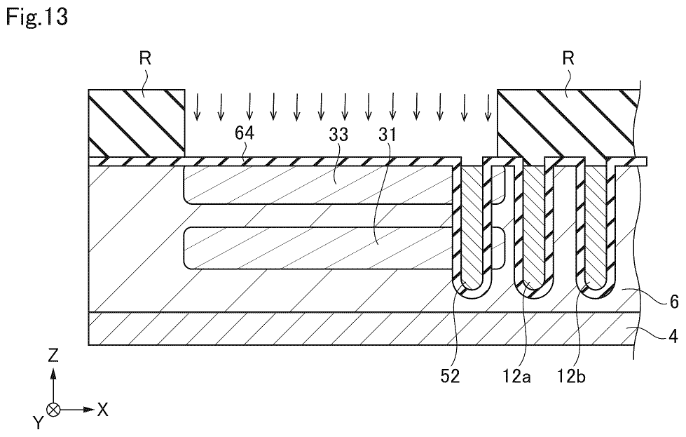

FIGS. 12A to 13 are schematic cross-sectional views showing a process of manufacturing the semiconductor device 120 of embodiments.

A method for manufacturing a semiconductor device of embodiments includes: forming a tenth semiconductor layer of second conductivity type in a layer of a second semiconductor layer of first conductivity type, the layer of the second semiconductor layer becoming a fifth semiconductor layer; forming a first trench in the second semiconductor layer, the tenth semiconductor layer being not formed in the second semiconductor layer; forming a second trench in the second semiconductor layer adjacent to the first trench, the tenth semiconductor layer being formed in the second semiconductor layer; forming a fourth insulating film on the second semiconductor layer and inside the first trench and the second trench; and forming a fifth semiconductor layer of first conductivity type or second conductivity type having a lower concentration of impurities of first conductivity type than the second semiconductor layer by diffusing impurities of second conductivity type contained in the tenth semiconductor layer into the second semiconductor layer, the tenth semiconductor layer being formed in the second semiconductor layer.

Unlike the semiconductor device 100 according to the first embodiment, in the case of the semiconductor device 120 of embodiments, the semiconductor layer 60 and the semiconductor layer 62 are not formed, and the first trench 11a, the first trench 11b, and the second trench 51a are formed in the drift layer 6 (FIG. 12A). Then, the insulating film 64 containing silicon oxide is formed on the drift layer 6 and inside the first trench 11 and the second trench 51 by using a thermal oxidation method, for example (FIG. 12B). Then, the first field plate electrode 12 is formed in the first trench 11 by using, for example, a chemical vapor deposition (CVD) method. In addition, the second field plate electrode 52 is formed in the second trench 51 (FIG. 12C).

Then, using the resist mask R provided on the first field plate electrode 12 as a mask, ion implantation of p-type impurities is performed from above the second field plate electrode 52 and the drift layer 6 to form the seventh semiconductor layer 33 and the eighth semiconductor layer 31 (FIG. 13A). The subsequent steps are the same as those in the first and second embodiments, and accordingly, will be omitted.

In the semiconductor device 120 of embodiments, by providing the seventh semiconductor layer 33 and the eighth semiconductor layer 31, it is possible to extend the depletion layer from the first insulating layer 34 side to the drain layer 4 side.

Through the semiconductor device 120 of embodiments, it is also possible to provide a highly reliable semiconductor device.

### Fourth Embodiment

A semiconductor device of embodiments is different from the semiconductor devices according to the first to third embodiments in that a width of the fifth electrode in a plane crossing a direction from the first semiconductor layer toward the second semiconductor layer is smaller than widths of the third electrode and the fourth electrode in the plane crossing the direction from the first semiconductor layer toward the second semiconductor layer.

In addition, the semiconductor device of embodiments is different from the semiconductor devices according to the first to third embodiments in that a plurality of third insulating films and a plurality of fifth electrodes are further provided and the plurality of third insulating films and the plurality of fifth electrodes are arranged at intervals different from the interval of the first insulating film and the first field plate electrode such that, in a plane crossing the direction from the first semiconductor layer toward the second semiconductor layer, the sum of the area of the plurality of third insulating films and the area of the plurality of fifth electrodes is 0.5 to 2 times the area of the fifth semiconductor layer in which the plurality of third insulating films and the plurality of fifth electrodes are not provided.

Here, the description of the content overlapping the first to third embodiments will be omitted.

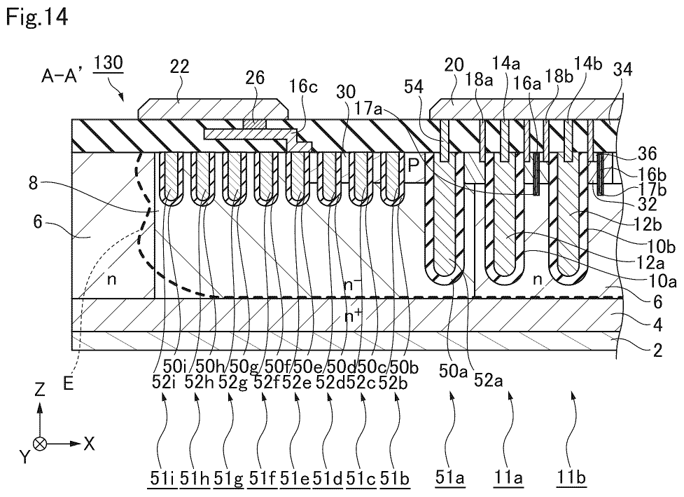

FIG. 14 is a schematic cross-sectional view of a semiconductor device 130 of embodiments.

Unlike the semiconductor device according to the second embodiment, in the semiconductor device 130, the widths of the second field plate electrode 52b, the second field plate electrode 52c, the second field plate electrode 52d, the second field plate electrode 52e, the second field plate electrode 52f, the second field plate electrode 52g, the second field plate electrode 52h, and the second field plate electrode 52i in the XY plane are smaller than the widths of the second field plate electrode 52a, the first field plate electrode 12a, and the first field plate electrode 12b in the XY plane.

In addition, the second field plate electrode 52b, the second field plate electrode 52c, the second field plate electrode 52d, the second field plate electrode 52e, the second field plate electrode 52f, the second field plate electrode 52g, the second field plate electrode 52h, and the second field plate electrode 52i are not electrically connected to the source wiring 20.

In addition, the sum of the areas of the second insulating film 50b, the second insulating film 50c, the second insulating film 50d, the second insulating film 50e, the second insulating film 50f, the second insulating film 50g, the second insulating film 50h, and the second insulating film 50i and the areas of the second field plate electrode 52b, the second field plate electrode 52c, the second field plate electrode 52d, the second field plate electrode 52e, the second field plate electrode 52f, the second field plate electrode 52g, the second field plate electrode 52h, and the second field plate electrode 52i in a plane parallel to the XY plane is preferably 0.5 to 2 times the area of the termination layer 8, in which the second insulating film 50b, the second insulating film 50c, the second insulating film 50d, the second insulating film 50e, the second insulating film 50f, the second insulating film 50g, the second insulating film 50h, and the second insulating film 50i and the second field plate electrode 52b, the second field plate electrode 52c, the second field plate electrode 52d, the second field plate electrode 52e, the second field plate electrode 52f, the second field plate electrode 52g, the second field plate electrode 52h, and the second field plate electrode 52i are not provided, in the plane parallel to the XY plane. This is because, in the process of manufacturing the semiconductor device 130 of embodiments, p-type impurities are injected and diffused into the upper surface of the termination layer 8 and the bottom portion of the second trench 51, which is appropriate from the viewpoint of making the n-type impurity concentration in the termination layer 8 uniform.

In the semiconductor device 130 of embodiments, the second insulating film 50a is an example of the second insulating film. In addition, the second insulating film 50b, the second insulating film 50c, the second insulating film 50d, the second insulating film 50e, the second insulating film 50f, the second insulating film 50g, the second insulating film 50h, and the second insulating film 50i are examples of the plurality of third insulating films. In addition, the second field plate electrode 52b, the second field plate electrode 52c, the second field plate electrode 52d, the second field plate electrode 52e, the second field plate electrode 52f, the second field plate electrode 52g, the second field plate electrode 52h, and the second field plate electrode 52i are examples of the plurality of fifth electrodes.

By appropriately adjusting the depths of the second trench 51b, the second trench 51c, the second trench 51d, the second trench 51e, the second trench 51f, the second trench 51g, the second trench 51h, and the second trench 51i and the sizes of the openings, it is possible to process the trenches collectively, including the first trench 11a, the first trench 11b, and the second trench 51a.

In addition, by appropriately adjusting the depths of the second trench 51b, the second trench 51c, the second trench 51d, the second trench 51e, the second trench 51f, the second trench 51g, the second trench 51h, and the second trench 51i and the sizes of the openings, it is possible to easily diffuse p-type impurities throughout the drift layer 6 by implanting ions into the surface of the drift layer 6 and the bottom portions of the second trenches 51b to 51i even if ion implantation using high energy is not performed, thereby forming the termination layer 8.

Through the semiconductor device 130 of embodiments, it is also possible to provide a highly reliable semiconductor device.

While certain embodiments have been described, embodiments have been presented as examples, and are not intended to limit the scope of the inventions. Embodiments can be implemented in various other forms, and various omissions, replacements, and modifications can be made without departing from the scope of the inventions. Embodiments or their modifications are included in the scope or gist of the inventions, and are included in the scope of the inventions described in the claims and their equivalents.

In addition, embodiments described above can be summarized as the following technical proposals.

### Technical Proposal 1

A semiconductor device, including:
a first electrode;
a first semiconductor layer of a first conductivity type provided on the first electrode;
a second semiconductor layer of the first conductivity type provided on the first semiconductor layer, and the second semiconductor layer having a lower concentration of impurities of the first conductivity type than the first semiconductor layer;
a third semiconductor layer of a second conductivity type provided on the second semiconductor layer;
a fourth semiconductor layer of the first conductivity type provided on the third semiconductor layer;
a fifth semiconductor layer provided around the second semiconductor layer on the first semiconductor layer,
   the fifth semiconductor layer of the first conductivity type and having a lower concentration of impurities of the first conductivity type than the second semiconductor layer, or
   the fifth semiconductor layer of the second conductivity type;
a second electrode provided in the third semiconductor layer;
a third electrode provided in the second semiconductor layer and the third semiconductor layer, the third electrode facing the second semiconductor layer and the third semiconductor layer via a first insulating film; and
a fourth electrode provided in the fifth semiconductor layer adjacent to the second semiconductor layer, the fourth electrode being spaced apart from the first insulating film, and the fourth electrode facing the fifth semiconductor layer via a second insulating film.

### Technical Proposal 2

The semiconductor device according to technical proposal 1, further including:
a sixth semiconductor layer of the second conductivity type provided on the fifth semiconductor layer, the sixth semiconductor layer being connected to the third semiconductor layer, and the sixth semiconductor layer having a lower concentration of impurities of second conductivity type than the third semiconductor layer.

### Technical Proposal 3

The semiconductor device according to technical proposal 1, further including:
a fifth electrode provided in the fifth semiconductor layer, the fifth electrode facing the fifth semiconductor layer via a third insulating film, the third insulating film being spaced apart from the second insulating film, and the fourth electrode being provided between the third electrode and the fifth electrode.

### Technical Proposal 4

The semiconductor device according to technical proposal 3,
wherein a width of the fifth electrode in a plane crossing a direction from the first semiconductor layer toward the second semiconductor layer is smaller than widths of the third electrode and the fourth electrode in the plane crossing the direction from the first semiconductor layer toward the second semiconductor layer.

### Technical Proposal 5

The semiconductor device according to technical proposal 4, further including:
a plurality of the third insulating films and a plurality of the fifth electrodes,
wherein, in the plane crossing the direction from the first semiconductor layer toward the second semiconductor layer, a sum of areas of the third insulating films and areas of the fifth electrodes is 0.5 to 2 times an area of the fifth semiconductor layer not provided with the third insulating films and the fifth electrodes.

### Technical Proposal 6

The semiconductor device according to technical proposal 1, further including:
a first insulating layer provided on the third semiconductor layer and the fifth semiconductor layer;
a first wiring provided on the first insulating layer on the third semiconductor layer, and the first wiring being electrically connected to the third electrode and the fourth electrode;
a second wiring provided on the first insulating layer on the fifth semiconductor layer; and
a third wiring provided in the first insulating layer on the fifth semiconductor layer, and the third wiring electrically connecting the second electrode and the second wiring.

### Technical Proposal 7

A semiconductor device, including:
a first electrode;
a first semiconductor layer of a first conductivity type provided on the first electrode;
a second semiconductor layer of the first conductivity type provided on the first semiconductor layer, and the second semiconductor layer having a lower concentration of impurities of the first conductivity type than the first semiconductor layer;
a third semiconductor layer of a second conductivity type provided on the second semiconductor layer;
a fourth semiconductor layer of the first conductivity type provided on the third semiconductor layer;
a seventh semiconductor layer of the second conductivity type provided on the second semiconductor layer around the third semiconductor layer, the seventh semiconductor layer being connected to the third semiconductor layer, and the seventh semiconductor layer having a lower concentration of impurities of the second conductivity type than the third semiconductor layer;
an eighth semiconductor layer of the second conductivity type provided in the second semiconductor layer below the seventh semiconductor layer, and the eighth semiconductor layer having a lower concentration of impurities of the second conductivity type than the third semiconductor layer;
a second electrode provided in the third semiconductor layer;
a third electrode provided in the second semiconductor layer and the third semiconductor layer, the third electrode facing the second semiconductor layer and the third semiconductor layer via a first insulating film; and
a fourth electrode provided in the seventh semiconductor layer, in the eighth semiconductor layer, and in the second semiconductor layer between the seventh semiconductor layer and the eighth semiconductor layer, the fourth electrode facing the seventh semiconductor layer, the eighth semiconductor layer, and the second semiconductor layer via a second insulating film.

### Technical Proposal 8

The semiconductor device according to technical proposal 7, further including:
a ninth semiconductor layer of the second conductivity type provided between the seventh semiconductor layer and the eighth semiconductor layer, the ninth semiconductor layer being connected to the seventh semiconductor layer and the eighth semiconductor layer, and the ninth semiconductor layer having a lower concentration of impurities of the second conductivity type than the third semiconductor layer.

### Technical Proposal 9

The semiconductor device according to technical proposal 7, further including:
a first insulating layer provided on the third semiconductor layer and the seventh semiconductor layer;
a first wiring provided on the first insulating layer on the third semiconductor layer, and the first wiring being electrically connected to the third electrode and the fourth electrode;
a second wiring provided on the first insulating layer on the seventh semiconductor layer; and
a third wiring provided in the first insulating layer on the seventh semiconductor layer, and the third wiring electrically connecting the second electrode and the second wiring.

### Technical Proposal 10

A method for manufacturing a semiconductor device, including:
forming a tenth semiconductor layer of a second conductivity type in a layer of a second semiconductor layer of a first conductivity type, the layer of the second semiconductor layer to be a fifth semiconductor layer;
forming a first trench in a part of the second semiconductor layer where the tenth semiconductor layer being not formed;
forming a second trench in a part of the second semiconductor layer where the tenth semiconductor layer being formed, and the second trench being adjacent to the first trench;
forming a fourth insulating film on the second semiconductor layer and inside the first trench and the second trench; and
forming a fifth semiconductor layer by diffusing impurities of the second conductivity type contained in the tenth semiconductor layer into the second semiconductor layer, the tenth semiconductor layer being formed in the second semiconductor layer,
   the fifth semiconductor layer of the first conductivity type and having a lower concentration of impurities of the first conductivity type than the second semiconductor layer, or
   the fifth semiconductor layer of the second conductivity type.

What is claimed is:

1. A semiconductor device, comprising:
a first electrode;
a first semiconductor layer of a first conductivity type provided on the first electrode;
a second semiconductor layer of the first conductivity type provided on the first semiconductor layer, and the second semiconductor layer having a lower concentration of impurities of the first conductivity type than the first semiconductor layer;
a third semiconductor layer of a second conductivity type provided on the second semiconductor layer;
a fourth semiconductor layer of the first conductivity type provided on the third semiconductor layer;
a fifth semiconductor layer provided around the second semiconductor layer on the first semiconductor layer,
the fifth semiconductor layer of the first conductivity type and having a lower concentration of impurities of the first conductivity type than the second semiconductor layer, or
the fifth semiconductor layer of the second conductivity type;
a second electrode provided in the third semiconductor layer;
a third electrode provided in the second semiconductor layer and the third semiconductor layer, the third electrode facing the second semiconductor layer and the third semiconductor layer via a first insulating film; and
a fourth electrode provided in the fifth semiconductor layer adjacent to the second semiconductor layer, the fourth electrode being spaced apart from the first insulating film, and the fourth electrode facing the fifth semiconductor layer via a second insulating film.

2. The semiconductor device according to claim 1, further comprising:
a sixth semiconductor layer of the second conductivity type provided on the fifth semiconductor layer, the sixth semiconductor layer being connected to the third semiconductor layer, and the sixth semiconductor layer having a lower concentration of impurities of second conductivity type than the third semiconductor layer.

3. The semiconductor device according to claim 1, further comprising:
a fifth electrode provided in the fifth semiconductor layer, the fifth electrode facing the fifth semiconductor layer via a third insulating film, the third insulating film being spaced apart from the second insulating film, and the fourth electrode being provided between the third electrode and the fifth electrode.

4. The semiconductor device according to claim 3,
wherein a width of the fifth electrode in a plane crossing a direction from the first semiconductor layer toward the second semiconductor layer is smaller than widths of the third electrode and the fourth electrode in the plane crossing the direction from the first semiconductor layer toward the second semiconductor layer.

5. The semiconductor device according to claim 4, further comprising:
a plurality of the third insulating films and a plurality of the fifth electrodes,
wherein, in the plane crossing the direction from the first semiconductor layer toward the second semiconductor layer, a sum of areas of the third insulating films and areas of the fifth electrodes is 0.5 to 2 times an area of the fifth semiconductor layer not provided with the third insulating films and the fifth electrodes.

6. The semiconductor device according to claim 1, further comprising:
a first insulating layer provided on the third semiconductor layer and the fifth semiconductor layer;
a first wiring provided on the first insulating layer on the third semiconductor layer, and the first wiring being electrically connected to the third electrode and the fourth electrode;
a second wiring provided on the first insulating layer on the fifth semiconductor layer; and
a third wiring provided in the first insulating layer on the fifth semiconductor layer, and the third wiring electrically connecting the second electrode and the second wiring.

7. A semiconductor device, comprising:
a first electrode;
a first semiconductor layer of a first conductivity type provided on the first electrode;
a second semiconductor layer of the first conductivity type provided on the first semiconductor layer, and the second semiconductor layer having a lower concentration of impurities of the first conductivity type than the first semiconductor layer;
a third semiconductor layer of a second conductivity type provided on the second semiconductor layer;
a fourth semiconductor layer of the first conductivity type provided on the third semiconductor layer;
a seventh semiconductor layer of the second conductivity type provided on the second semiconductor layer around the third semiconductor layer, the seventh semiconductor layer being connected to the third semiconductor layer, and the seventh semiconductor layer having a lower concentration of impurities of the second conductivity type than the third semiconductor layer;
an eighth semiconductor layer of the second conductivity type provided in the second semiconductor layer below the seventh semiconductor layer, and the eighth semiconductor layer having a lower concentration of impurities of the second conductivity type than the third semiconductor layer;
a second electrode provided in the third semiconductor layer;
a third electrode provided in the second semiconductor layer and the third semiconductor layer, the third electrode facing the second semiconductor layer and the third semiconductor layer via a first insulating film; and
a fourth electrode provided in the seventh semiconductor layer, in the eighth semiconductor layer, and in the second semiconductor layer between the seventh semiconductor layer and the eighth semiconductor layer, the fourth electrode facing the seventh semiconductor layer, the eighth semiconductor layer, and the second semiconductor layer via a second insulating film.

8. The semiconductor device according to claim 7, further comprising:
a ninth semiconductor layer of the second conductivity type provided between the seventh semiconductor layer and the eighth semiconductor layer, the ninth semiconductor layer being connected to the seventh semiconductor layer and the eighth semiconductor layer, and the ninth semiconductor layer having a lower concentration of impurities of the second conductivity type than the third semiconductor layer.

9. The semiconductor device according to claim 7, further comprising:
a first insulating layer provided on the third semiconductor layer and the seventh semiconductor layer;
a first wiring provided on the first insulating layer on the third semiconductor layer, and the first wiring being electrically connected to the third electrode and the fourth electrode;
a second wiring provided on the first insulating layer on the seventh semiconductor layer; and
a third wiring provided in the first insulating layer on the seventh semiconductor layer, and the third wiring electrically connecting the second electrode and the second wiring.

10. A method for manufacturing a semiconductor device, comprising:
forming a tenth semiconductor layer of a second conductivity type in a layer of a second semiconductor layer of a first conductivity type, the layer of the second semiconductor layer to be a fifth semiconductor layer;
forming a first trench in a part of the second semiconductor layer where the tenth semiconductor layer being not formed;
forming a second trench in a part of the second semiconductor layer where the tenth semiconductor layer being formed, and the second trench being adjacent to the first trench;
forming a fourth insulating film on the second semiconductor layer and inside the first trench and the second trench; and
forming a fifth semiconductor layer by diffusing impurities of the second conductivity type contained in the tenth semiconductor layer into the second semiconductor layer, the tenth semiconductor layer being formed in the second semiconductor layer,
the fifth semiconductor layer of the first conductivity type and having a lower concentration of impurities of the first conductivity type than the second semiconductor layer, or
the fifth semiconductor layer of the second conductivity type.
